(19) United States
(12) Patent Application Publication
(10) Pub. No.: US 2011/0305068 A1
(43) Pub. Date: Dec. 15, 2011

(54) RESISTANCE RANDOM ACCESS CHANGE MEMORY DEVICE

(75) Inventors: Makoto Kitagawa, Kanagawa (JP); Tsunenori Shiimoto, Kanagawa (JP); Hiroshi Yoshihara, Nagasaki (JP)

(73) Assignee: SONY CORPORATION, Tokyo (JP)

(21) Appl. No.: 13/116,590

(22) Filed: May 26, 2011

(30) Foreign Application Priority Data
Jun. 10, 2010 (JP) 2010-133295

(51) Int. Cl. G11C 11/00

(52) U.S. Cl. 365/148

(57) ABSTRACT

A resistance random access change memory device includes: a memory cell array in which plural memory cells having current paths with series-connected access transistors and variable resistive elements are two-dimensionally arranged; plural bit lines that connect one ends of the current paths; plural source lines that connect the other ends of the current paths; and plural word lines that control conduction and non-conduction of the access transistors, wherein bit line contacts are shared between two memory cells to which the word lines are adjacently provided, and pairs of memory cells are formed, all of the pairs of memory cells connected to the adjacent two bit lines are connected to the corresponding source lines via individual source line contacts, and the source lines are formed by a wiring layer upper than that of the bit lines with a larger pitch than that of the bit lines.

### FIELD

The present disclosure relates to a resistance random access change memory device having memory cells with series-connected access transistors and variable resistive elements.

### BACKGROUND

Nonvolatile memory devices used by application of pre-charge voltages to bit lines and readout of the differences between discharging rates have been known.

As a representative of nonvolatile semiconductor memory devices to which the readout method may be applied, there is a (flash) EEPRAPM.

On the other hand, in order to replace an FG-type (flash) EEPROM, as a nonvolatile memory device for fast data rewriting, a resistance random access change memory device attracts attention.

As the resistance random access change memory device, the so-called RRAM that resistance changes at input and output of conducting ions to and from conducting films within variable resistive elements Rcell are allowed to correspond to the memory statuses is known (for example, see Non-Patent Documents 1 and 2 (K. Aratani, et al., “A Novel Resistance Memory with High Scalability and Nanosecond Switching”, Technical Digest IEDM 2007, pp. 783-786, and Shyh-Shyuan Sheu, et al., “A 5 ns Fast Write Multi-Level Non-Volatile 1 K bits RRAM Memory with Advance Write Scheme”, 2009 Symposium on VLSI Circuits Digest of Technical Papers pp. 82-83”)).

Each memory cell of the RRAM includes an access transistor and a variable resistive element series-connected between a bit line and a source line (also referred to as “plate line”).

Particularly, Non-Patent Document 2 discloses a device configuration that can write and erase data faster with lighter wiring load by switching the respective bit lines and source lines using a multiplexer (MUX).

### SUMMARY

In the RRAM described in Non-Patent Document 1, the first electrode of the variable resistive element is connected to the bit line with lighter load via the access transistor and the voltage of the bit line changes faster.

However, the second electrode of the variable resistive element is connected to the plate line and the plate line is shared among plural memory cells in the row direction and the column direction. Accordingly, the plate line has a heavy load and fast voltage change may not be made.

Therefore, the RRAM is unsuitable for the random access operation.

On the other hand, the RRAM described in Non-Patent Document 2 discloses the configuration in which this point is improved and the second electrode of the variable resistive element is driven by the source line in the column direction.

There is no disclosure in either Non-Patent Document 1 or 2 that the specific use of the multilayer wiring layer and layout containing wiring that can reduce the unit area per cell.

Particularly, it is necessary to work the bit line in the minimum working dimension F, however, if the source line is similarly worked in F, the integration difficulty becomes higher and the yield becomes lower. In the resistance random access change memory device, the use of the multilayer wiring layer and the layout containing wiring that can prevent the reduction of the yield has not been proposed yet.

Thus, it is desirable to provide a resistance random access change memory device that can reduce the unit area per memory cell and prevent reduction of yield in wiring work.

A resistance random access change memory device according to an embodiment of the disclosure includes a memory cell array, plural bit lines, plural source lines, and plural word lines.

In the memory cell array, plural memory cells having current paths with series-connected access transistors and variable resistive elements are two-dimensionally arranged.

The plural bit lines connect one ends of the current paths.

The plural source lines connect the other ends of the current paths.

The plural word lines control conduction and non-conduction of the access transistors.

Bit line contacts are shared between two memory cells to which the word lines are adjacently provided and pairs of memory cells are formed.

All of the pairs of memory cells connected to the adjacent two bit lines are connected to the corresponding source lines via individual source line contacts.

Further, the source lines are formed by a wiring layer upper than that of the bit lines with a larger pitch than that of the bit lines.

In the embodiment of the disclosure, preferably, the pairs of memory cells are alternately connected to the adjacent two bit lines in a column direction.

Alternatively, preferably, the memory cell array has an arrangement of pairs of memory cells selected by different word lines between the pairs of memory cells connected to odd-numbered bit lines and the pairs of memory cells connected to even-numbered bit lines.

Further, as another preferable embodiment, the pairs of memory cells in a number selectable by all word lines are connected to the respective adjacent two bit lines.

According to the above described configuration, the bit line contacts are shared between two memory cells within the respective pairs of memory cells. Accordingly, in the case where the bit lines connecting the bit line contacts are formed by a certain wiring layer (for example, the first layer), the source lines are formed by a wiring layer upper than the wiring layer (for example, the first layer) forming the bit lines. The respective source lines connect the source line contacts, and it is necessary to wire the bit lines at the lower layer side around the source line contacts.

In the embodiment of the disclosure, the bit line contacts are shared between the two memory cells, and thus, the number of contacts to be electrically connected by the respective bit lines is reduced and the degree of freedom of wiring of the bit lines is higher by the reduction. Because of the sharing of the bit line contacts and the formation of the bit lines and source lines by different wiring layers, the unit area per memory cell is smaller.

Further, the two memory cells (pair of memory cells) sharing the bit line contacts are connected to different word lines. Accordingly, as in the preferable example, control of selection and non-selection by the different word lines (control of the access transistors) may be performed.

Furthermore, the wiring pitch of the source lines in the upper layer is relaxed compared to that of the bit lines, and thus, the reduction of yield at wiring formation may be prevented.

According to the embodiment of the disclosure, a resistance random access change memory device that can reduce the unit area per memory cell and prevent reduction of yield in wiring work may be provided.

### BRIEF DESCRIPTION OF THE DRAWINGS

FIGS. 1A and 1B are equivalent circuit diagrams of a memory cell common to the first and second embodiments and modified examples.

FIG. 2 is a device sectional structure diagram of adjacent two memory cell parts.

FIGS. 3A and 3B show sections and operations of a variable resistive element.

FIG. 4 is a block diagram of an IC chip (memory device) common to the first and second embodiments.

FIG. 5 is a circuit diagram of an X selector.

FIG. 6 is a circuit diagram of a Y selector.

FIG. 7 is a circuit diagram of two WL driver units.

FIG. 8 is a circuit diagram of a CSW driver unit.

FIG. 9 is an equivalent circuit diagram of a memory cell array related to the first embodiment.

FIG. 10 is a plan view halfway through formation of the memory cell array related to the first embodiment.

FIG. 11 is a plan view halfway through the formation of the memory cell array subsequent to FIG. 10.

FIG. 12 is a plan view halfway through the formation of the memory cell array subsequent to FIG. 11.

FIG. 13 is a perspective view of a memory cell related to the first and second embodiments.

FIG. 14 is a plan view showing modified example 1 of a worked shape of source lines.

FIG. 15 is a schematic sectional view showing modified example 2 of overlapping widths of source line contacts and the source line.

FIG. 16 is a circuit diagram showing a main part of BL drivers and SL drivers related to the first embodiment.

FIG. 17 shows an operation waveform chart related to the first embodiment.

FIG. 18 shows another operation waveform chart related to the first embodiment.

FIG. 19 shows another operation waveform chart related to the first embodiment.

FIG. 20 shows another operation waveform chart related to the first embodiment.

FIG. 21 is an equivalent circuit diagram of a memory cell array related to the second embodiment.

FIG. 22 is a plan view halfway through formation of the memory cell array related to the second embodiment.

FIG. 23 is a plan view halfway through the formation of the memory cell array subsequent to FIG. 22.

FIG. 24 is a plan view halfway through the formation of the memory cell array subsequent to FIG. 23.

FIG. 25 is a plan view showing modified example 3 of a worked shape of source lines.

FIG. 26 is a circuit diagram showing a main part of BL drivers and SL drivers related to the second embodiment.

FIG. 27 shows an operation waveform chart related to the second embodiment.

FIG. 28 shows another operation waveform chart related to the second embodiment.

FIG. 29 shows another operation waveform chart related to the second embodiment.

FIG. 30 shows another operation waveform chart related to the second embodiment.

FIG. 31 is a circuit diagram of a circuit part (within a control circuit 11) that generates enable signals.

### DETAILED DESCRIPTION

Embodiments of the disclosure will be explained with reference to the drawings in the following order.

1. First Embodiment: Staggered arrangement of pairs of memory cells in row direction and column direction

2. Second Embodiment: Matrix arrangement of pairs of memory cells

### 1. First Embodiment

### [Memory Cell Configuration]

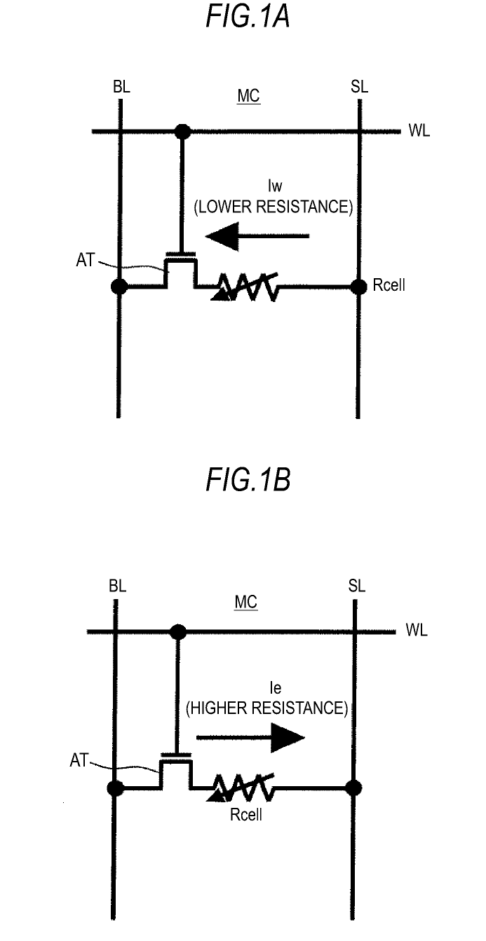

FIGS. 1A and 1B are equivalent circuit diagrams of a memory cell common to the embodiments of the disclosure. Note that FIG. 1A shows a direction of a write current Iw and FIG. 1B shows a direction of an erase current Ie, and the memory cell configuration itself is common to both drawings.

The memory cell MC illustrated in FIG. 1A and 1B has one variable resistive element Rcell as “variable resistive element Rcell” and one access transistor AT.

One end of the variable resistive element Rcell is connected to a source line SL, the other end is connected to a source of the access transistor AT, and a drain of the access transistor AT is connected to a bit line BL and a gate is connected to a word line WL, respectively.

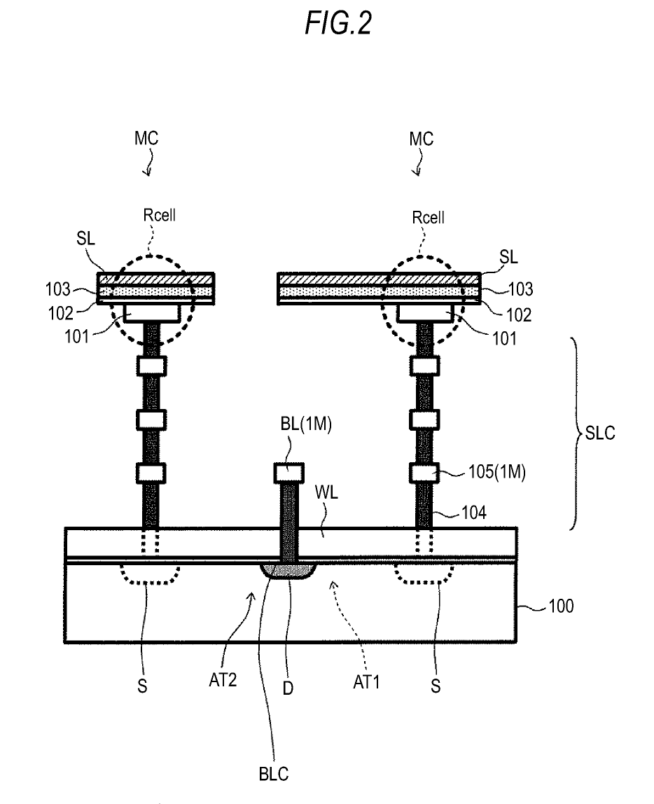

FIG. 2 shows a device structure of a part corresponding to adjacent two memory cell parts. FIG. 2 is a schematic sectional view with no shaded part. Further, the blank part in FIG. 2 not particularly mentioned is filled with an insulating film, or forms (some of) another part.

In the memory cell MC illustrated in FIG. 2, its access transistor AT is formed on a semiconductor substrate 100.

More specifically, two impurity regions to be the source (S) and the drain (D) of the access transistor AT are formed on the semiconductor substrate 100, and a gate electrode of polysilicon etc. is formed via a gate insulating film intermediate on the substrate region between the impurity regions. Here, the gate electrode forms the word line WL wired in the row direction (the lateral direction in FIG. 2), the impurity region to be the drain (D) is provided at the front side of the word line WL (at the front side in the perpendicular direction to the paper surface in FIG. 2), and the impurity region to be the source (S) is provided at the depth side (of the paper surface).

The drain (D) is shared between two memory cells, and connected to the bit line BL formed by a first wiring layer (1M) via the common bit line contact BLC 12.

Note that the common bit line contact BLC 12 is shared between two access transistors adjacent in the bit line direction of an access transistor AT1 at the depth side of the paper surface and an access transistor AT2 at the front side of the paper surface in FIG. 2.

Two pairs of memory cells different from the pair of memory cells having the common bit line contact BLC are provided at one side and the other side in the word line direction with the common bit line contact BLC in between. The two sources (S) shown in FIG. 2 show source impurity regions of the different two pairs of memory cells.

Plugs 104 and landing pads 105 (formed from the wiring layer) are repeatedly stacked on the respective sources (S), and thereby, source line contacts SLC are formed. On the source line contacts SLC, variable resistive elements Rcell are formed. The variable resistive element Rcell may be formed in any layer of the multilayer wiring structure, and, here, the variable resistive element Rcell is formed roughly in the fourth to fifth layer.

The variable resistive element Rcell has a film configuration (stacked structure) with an insulating film 102 and a conducting film 103 between a lower electrode 101 and an upper electrode to be the source line SL.

As a material of the insulating film 102, for example, SiN, SiO₂, Gd₂O₃, or the like may be cited.

As a material of the conducting film 103, for example, a metal film, an alloy film (e.g. , a CuTe alloy film), a metal compound film, or the like containing one or more metal elements selected from Cu, Ag, Zr, Al may be cited. Note that other metal elements than Cu, Ag, Zr, Al may be used as long as they have properties to be easily ionized. Further, it is desirable that the element to be combined with at least one of Cu, Ag, Zr, Al is at least one element of S, Se, Te. The conducting film 103 is formed as “ion supply layer”.

FIG. 2 shows the two variable resistive elements Rcell connected to the different source lines SL. Here, the memory layers (insulating films 102), the ion supply layers (conducting films 103), and the source lines SL adjacent in the same direction as the bit line BL are respectively formed by the same layers. Further, as another configuration, the source lines SL are shared among the memory cells in the bit line direction, and the memory layers and the ion supply layers are independently formed with respect to each memory cell.

In the embodiment, the source lines SL may be formed by the wiring layer upper than that of the bit line BL. Here, the bit line BL is formed by the first wiring layer (1M) and the source lines SL are formed in the fourth and the fifth wiring layers. Note that the source lines SL may be formed from the second (2M) and the upper wiring layer in the example.

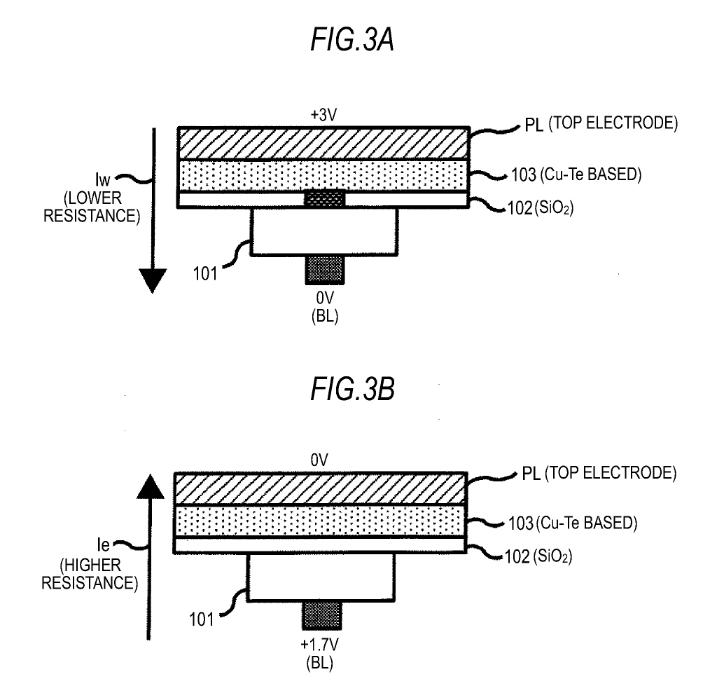

FIG. 3A and 3B show enlarged views of the variable resistive element Rcell with examples of current directions and applied voltage values.

FIG. 3A and 3B show the cases where the insulating film 102 is formed from SiO2 and the conducting film 103 is formed from a Cu—Te based alloy compound as an example.

In FIG. 3A, a voltage with the insulating film 102 side at the negative electrode side and the conducting film 103 side at the positive electrode side is applied to the lower electrode 101 and the upper electrode (source line SL). For example, the bit line BL is grounded at 0 [V] and, for example, +3 [V] is applied to the source line SL.

Then, Cu, Ag, Zr, Al contained in the conducting film 103 is ionized and has a property attracted to the negative electrode side. These metal conducting ions are implanted into the insulating film 102. Accordingly, the insulation property of the insulating film 102 becomes lower and has a conductive property with the lowering. As a result, a write current Iw in the direction shown in FIG. 3A flows. The operation is referred to as “write (operation)” or “set (operation)”.

On the other hand, a voltage with the insulating film 102 side at the positive electrode side and the conducting film 103 side at the negative electrode side is applied to the lower electrode 101 and the upper electrode (source line SL). For example, the source line SL is grounded at 0 [V] and, for example, +1.7 [V] is applied to the bit line BL.

Then, the conducting ions implanted into the insulating film 102 are returned to the conducting film 103 and reset in a state in which the resistance value is higher before writing. The operation is referred to as “erase (operation)” or “reset (operation)”. In resetting, an erase current Ie in the direction shown in FIG. 3B flows.

Note that, as below, “set” is used to mean “adequately implant conducting ions into the insulating film” and “reset” is used to mean “adequately extract conducting ions from the insulating film”.

In this regard, which status (set or reset) is writing status or erasing status of data is arbitrarily defined.

In the following explanation, the case where the insulation property of the insulating film 102 becomes lower and the resistance value of the entire variable resistive element Rcell becomes lower to an adequate level corresponds to “write (set)” of data. On the other hand, the case where the insulation property of the insulating film 102 is returned to the original initial state and the resistance value of the entire variable resistive element Rcell becomes higher to an adequate level corresponds to “erase (reset)”.

Here, normally, the arrows of the circuit symbols of the variable resistive element Rcell shown in FIGS. 1A and 1B are in the same direction of the current at setting (here, at writing).

By repeating the above described setting and resetting, a binary memory that reversibly changes the resistance value of the variable resistive element Rcell between the high-resistance state and the low-resistance state is realized. In addition, the variable resistive element Rcell functions as a nonvolatile memory because data is held even when the voltage application is stopped.

Note that, at setting, actually, the resistance value of the insulating film 102 changes depending on the amount of metal ions within the insulating film 102, and the insulating film 102 may be regarded as “memory layer” in which data is stored and held.

By forming the memory cell using the variable resistive element Rcell and providing many memory cells, a memory cell array of a resistance random access change memory may be formed. The resistance random access change memory includes the memory cell array and a drive circuit (peripheral circuit) therefor.

### [IC Chip Configuration]

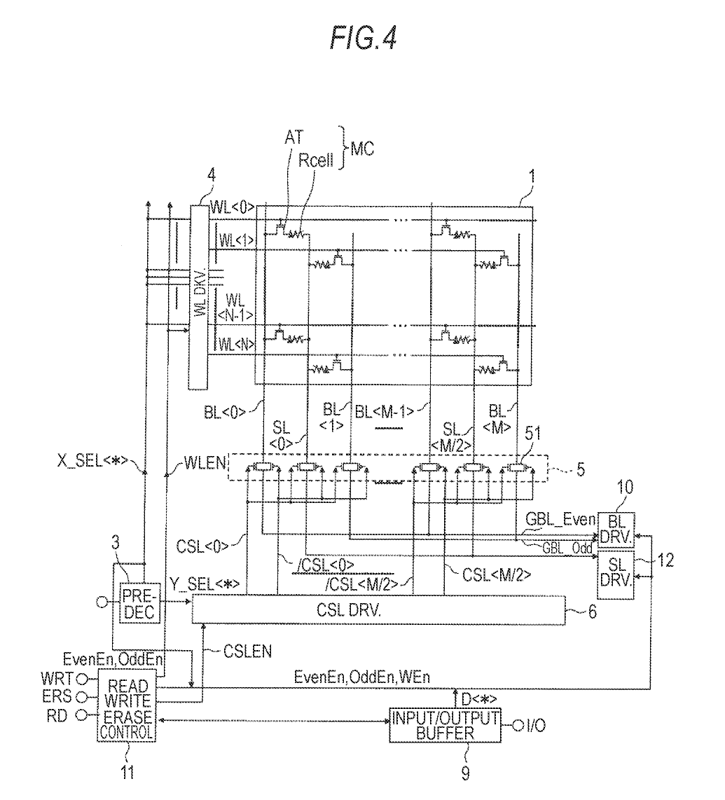

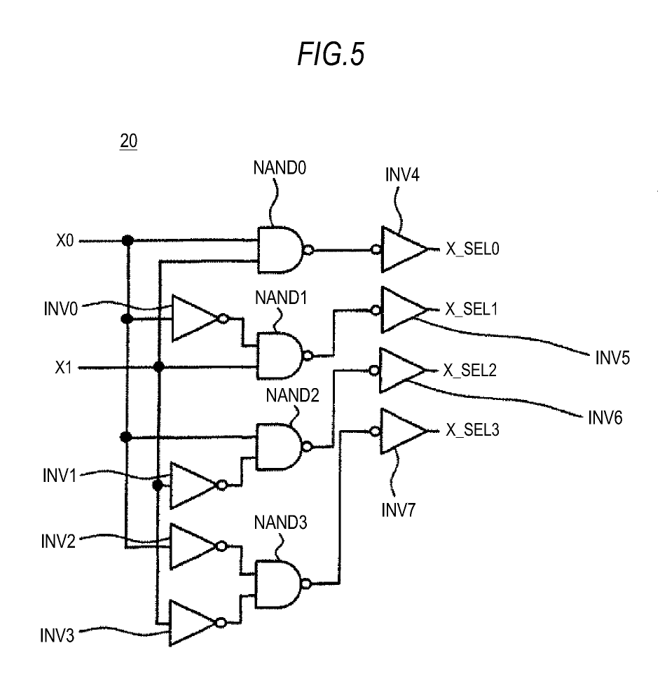

FIG. 4 is a block diagram of an IC chip.

The illustrated semiconductor memory device has a memory cell array 1 in which memory cells MC shown in FIGS. 1A to 3B are arranged in a matrix with (M+1) cells in the row direction and (N+1) cells in the column direction. The semiconductor memory device is formed by integrating the memory cell array 1 and a peripheral circuit therefor in the same semiconductor chip. Here, “N” and “M” are relatively large natural numbers, and their specific values are arbitrarily set.

In the memory cell array 1, (N+1) word lines WL<0> to WL<N> that respectively commonly connect the gates of the access transistors AT in the (M+1) memory cells MC arranged in the row direction are arranged at predetermined intervals in the column direction. Further, (M+1) bit lines BL<0> to BL<M> that respectively commonly connect the drains of the access transistors AT in the (N+1) memory cells MC arranged in the column direction are arranged at predetermined intervals in the row direction. The (M+1) bit lines BL<0> to BL<M> are drawn to the outside of the memory cell array 1.

(M/2) source lines SL that commonly connect nodes at the opposite side to the access transistors AT of the variable resistive elements Rcell in the column direction are arranged at predetermined intervals in the row direction. The (M/2) source lines SL are drawn to the outside of the memory cell array 1.

As shown in FIG. 4, the peripheral circuit includes a pre-decoder (PRE-DEC) 3 that serves as both an X (address) decoder and a Y (address) decoder, a WL driver (WL DRV.) 4, a column switch 5, and a CSL driver 6. The peripheral circuit includes an I/O buffer (Input/Output Buffer) 9. The peripheral circuit includes a write/erase driver (hereinafter, referred to as “BL driver (BL DRV.) 10”), a control circuit 11, and a source line driver (SL DRV.) 12.

Note that illustration of readout system circuits such as a sense amplifier, a logic block that performs write inhibit etc., circuits that generate various voltages from a power supply voltage, a generation control circuit of clock signals, etc. is omitted in FIG. 4.

The pre-decoder 3 separates an input address signal (Address) into an X address signal and a Y address signal. The pre-decoder 3 decodes the X address signal X_SEL using an X decode unit and decodes the Y address signal using a Y decode unit.

The X decode unit within the pre-decoder 3 is formed using an X selector (not shown) as a basic unit. The X decode unit is a circuit that decodes the X address signal input from the pre-decoder 3 and sends the selected X select signal X_SEL to the WL driver 4 based on the decode result. Details of the X selector will be described later.

The Y decode unit of the pre-decoder 3 is formed using an Y selector (not shown) as a basic unit. The Y decode unit is a circuit that decodes the input Y address signal and sends the selected Y select signal Y_SEL to the CSL driver 6 based on the decode result. Details of the Y selector will be described later.

The WL driver 4 includes (N+1) driver units (not shown) with respect to each word line WL. To the output of each WL driver unit, corresponding one word line of the (N+1) word lines WL<0> to WL<N> is connected. In response to the X select signal X_SEL input from the X decode unit of the pre-decoder 3, one of the WL driver units is selected. The WL driver unit is a circuit that applies a predetermined voltage to the word line WL connected to the output thereof when selected. Details of the WL driver unit will be described later.

The CSL driver 6 is formed using a CSW driver unit as a basic unit. The CSL driver 6 is a circuit that drives a column selection line CSL<0> and an inversion signal /CSL<0> thereof, . . . , a column selection line CSL<M/2> and an inversion signal /CSL<M/2> thereof as wiring for controlling the column switch 5. Details of the CSW driver unit will be described later.

The column switch 5 is an assembly of switches 51 formed by NMOS transistors (or PMOS transistors may be used) singly or transfer gates shown in FIG. 4. Here, the respective switches 51 are connected with respect to each bit line BL and source line SL, and there are (M+1+M/2) of them.

As below, the respective switches forming the column switch 5 are transfer gates.

The transfer gates of the column switch 5 corresponding to the bit lines BL control connections between the bit lines BL and global bit lines.

More specifically, the connections of the bit lines BL<0>, BL<2>, . . . of the even addresses (hereinafter, referred to as “even bit lines”) to an even global bit line GBL Even are controlled by the corresponding transfer gates. Similarly, the connections of the bit lines BL<1>, BL<3>, . . . of the odd addresses (hereinafter, referred to as “odd bit lines”) to an odd global bit line GBL Odd are controlled by the corresponding transfer gates.

The BL driver 10 is connected to the I/O buffer 9, data from outside is input from the I/O buffer 9 thereto, and the driver controls the global bit lines (GBL_Even, GBL_Odd) in response to the input data.

The SL driver 12 is connected to the I/O buffer 9, data from outside is input from the I/O buffer 9 thereto, and the driver controls the global bit lines (GBL_Even, GBL_Odd) in response to the input data.

For control of the BL driver 10 and the SL driver 12, various enable signals (EvenEn, OddEn, WEn) from the control circuit 11 are used.

A write enable signal WRT, an erase enable signal ERS, and a data readout signal RD are input to the control circuit 11, and the circuit operates based on the three signals.

The control circuit 11 has the following four functions:

(1) a function of word line control to provide WL selection enable signals WLEN to the individual WL driver units within the WL driver 4;

(2) a function of controlling the CSL driver 6 via the pre-decoder 3 (or directly) to individually bring the switches 51 into conduction or out of conduction;

(3) a function of providing an even column enable signal (EvenEn) and an odd column enable signal (OddEn) to the BL driver 10 to control supply of an operation voltage (magnitude and direction) at writing and erasing; and

(4) a function of controlling the readout system circuits such as a sense amplifier (not shown) and inhibit.

Note that, regarding various control signals output by the control circuit 11, only their signs are shown in FIG. 4 and details of level changes will be described later.

### [Control System Circuit]

Next, the X selector as a basic configuration of the X decode unit of the pre-decoder 3 and the Y selector as a basic configuration of the Y decode unit of the pre-decoder 3 will be explained. Subsequently, the WL driver unit as a basic configuration of the WL driver 4 will be explained.

FIG. 5 shows a circuit example of an X selector 20.

The X selector 20 illustrated in FIG. 5 includes four inverters INV0 to INV3 in the initial state, four NAND circuits NAND0 to NAND3 in the middle stage, and other four inverters INV4 to INV7 connected in the downstream stage.

The X selector 20 is a circuit that, when X address bits X0, X1 are input thereto, activates one of the X select signals X_SEL0 to X_SEL3 in response to the decode result (for example, brings the signal to a high level).

FIG. 5 is an example of 2-bit decode, and the X decode unit is realized to support inputs other than 2-bit input by expansion or multistage extension of the configuration in FIG. 5 in response to the number of bits of the X address signal to be input.

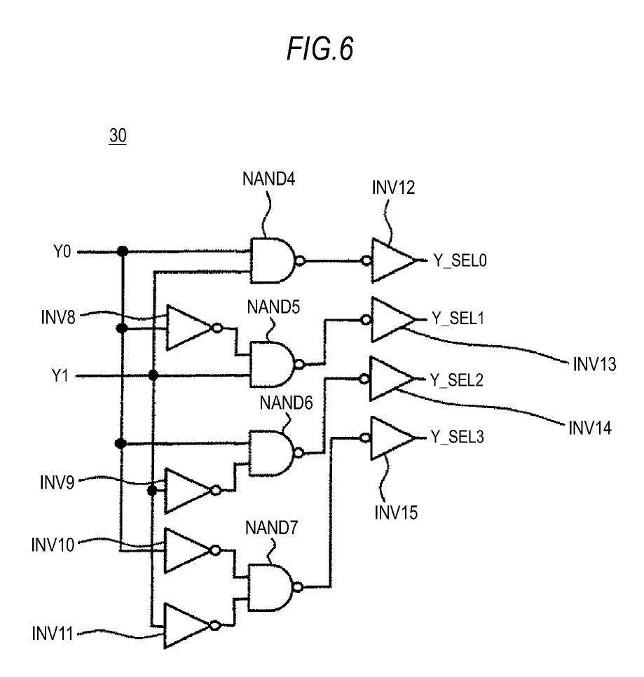

FIG. 6 shows a circuit example of an Y selector 30.

The Y selector 30 illustrated in FIG. 6 includes four inverters INV8 to INV11 in the initial stage, four NAND circuits NAND4 to NAND7 in the middle stage, and other four inverters INV12 to INV15 connected in the downstream stage.

The Y selector 30 is a circuit that, when Y address bits Y0, Y1 are input thereto, activates one of the Y select signals Y_SEL0 to Y_SEL3 in response to the decode result (for example, brings the signal to a high level).

FIG. 6 is an example of 2-bit decode, and the pre-decoder 3 is realized to support inputs other than 2-bit input by expansion or multistage extension of the configuration in FIG. 6 in response to the number of bits of the Y address signal to be input.

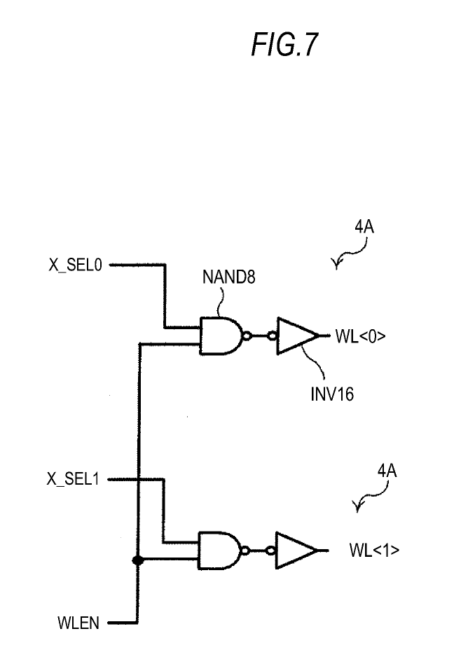

FIG. 7 is a circuit diagram showing two of WL driver units 4A.

The illustrated WL driver units 4A are provided within the WL driver 4 in the number of cells (N+1) in the column direction.

The (N+1) WL driver units 4A operate by one X select signal X_SEL0 or X_SEL1 selected (activated) by the X selector 20 shown in FIG. 5 etc. The WL driver unit 4A activates one word line WL<0> or WL<1> in response to the X select signal X_SEL0 or X_SEL1.

The WL driver unit 4A illustrated in FIG. 7 includes a NAND circuit NAND8 and an inverter INV16.

A WL selection enable signal WLEN is input to one input of the NAND circuit NAND8, the X select signal X_SEL0 or X_SEL1 is input to the other input, and the output of the NAND circuit NAND8 is connected to the input of the inverter INV16. The word line WL<0> or WL<1> connected to the output of the inverter INV16 is activated or deactivated.

The WL selection enable signal WLEN shown in FIG. 7 is generated in the control circuit 11 in FIG. 4 and provided to a row decoder 4.

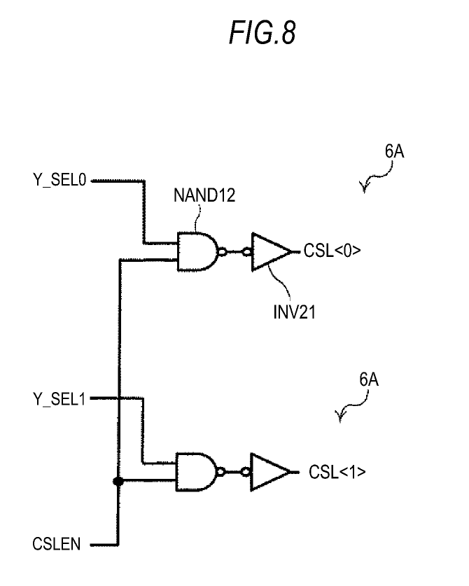

FIG. 8 is a circuit diagram showing two of CSL driver units 6A.

The illustrated CSL driver unit 6A illustrated in FIG. 8 includes a NAND circuit NAND12 and an inverter INV21 connected to the output thereof.

A CSL selection enable signal CSLEN is input to one input of the NAND circuit NAND12, and one Y select signal Y_SEL0 or Y_SEL1 selected (activated) by the Y selector 30 shown in FIG. 6 is input to the other input. When both the Y select signal Y_SEL0 or Y_SEL1 and the CSL enable signal CSLEN are active (at the high level), the output of the NAND circuit NAND12 is at the low level. Accordingly, the potential of the column selection line CSL<0> or CSL<1> connected to the output of the inverter INV21 transits to the active level (the high level in this example).

The potential of the column selection line CSL<0> or CSL<1> is input to the gate of the corresponding switch 51 (the NMOS transistor of the transfer gate) as shown in FIG. 4. Note that the inversion signal of the column selection line CSL<0> or CSL<1> is extracted from the connection node between the NAND circuit NAND12 and the inverter INV21, and input to the gate of the PMOS transistor of the transfer gate.

The CSL selection enable signal CSLEN shown in FIG. 8 is generated in the control circuit 11 in FIG. 4 and provided the CSL driver 6.

### [Cell Array Configuration]

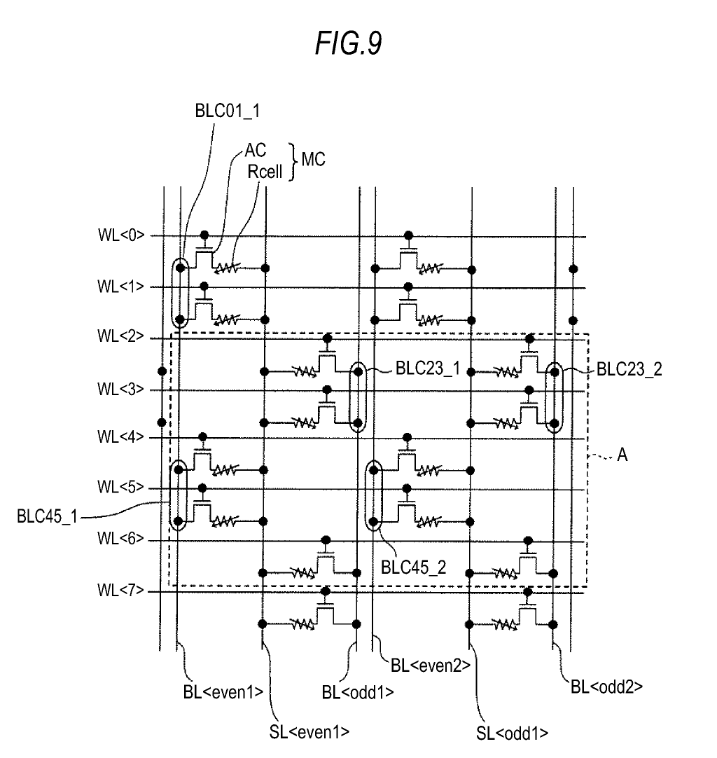

FIG. 9 shows an equivalent circuit diagram of the memory cell array 1 related to the first embodiment. In FIG. 9, only a part of the memory cell array 1 is shown.

In the memory cell array 1 illustrated in FIG. 9, memory cells MC having current paths with series-connected access transistors AT and variable resistive elements Rcell are two-dimensionally arranged.

More specifically, the common bit line contacts BLC are shared between two memory cells MC respectively connected to adjacent two word lines WL<even> and WL<odd> and belonging to the same memory cell columns, and pairs of memory cells are formed.

The pairs of memory cells are arranged in a staggered manner in the row direction and the column direction. Thereby, the pairs of memory cells connected to the odd-numbered bit lines BL<odd> and the pairs of memory cells connected to the even-numbered bit lines BL<even> are arranged to be selected by the different word lines.

For example, attention is focused on the memory cells within area A surrounded by a broken line in FIG. 9. Pairs of bit lines having a common bit line contact BLC23_1 and pairs of bit lines having a common bit line contact BLC45_1 are provided in the adjacent memory cell columns. Accordingly, the pairs of bit lines having the common bit line contact BLC23_1 are connected to the odd bit line BL<odd1>, and the pairs of bit lines having the common bit line contact BLC45₋1 are connected to the even bit line BL<even1>. Further, the two pairs of memory cells are controlled by different pairs of word lines of the pairs of word lines (WL<2>, WL<3>) and the pairs of word lines (WL<4>, WL<5>).

This is similar in other two memory cell columns within the area A. Further, this is similar in other pairs of memory cells (adjacent two memory cell columns) in the row direction and the column direction in areas other than the area A.

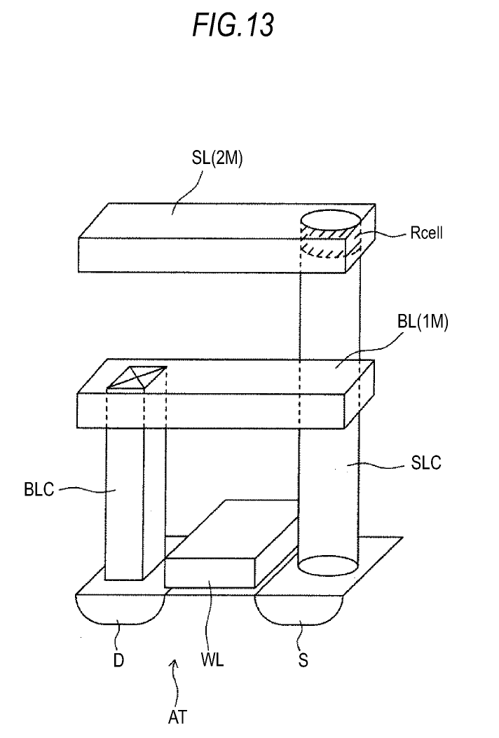

In one memory cell in this configuration example, as shown in FIG. 13, the bit line BL formed by the first wiring layer (1M) is connected to the drain (region) D of the access transistor AT via the common bit line contact BLC. The source line SL formed as the second wiring layer (2M) is connected to the source (region) S of the access transistor AT via the source line contact SLC.

As known from the perspective view, the variable resistive element Rcell may be regarded as being provided in the location of the source line contact SLC.

FIGS. 10 to 12 show plan views halfway through formation. These plan views correspond to the area A in FIG. 9.

FIG. 10 is a plan view showing formation of diffusion layers (sources S and drains D) to common bit line contacts BLC.

As shown in FIG. 10, active regions AR with respect to each pair of transistors are formed in a rectangular shape longitudinal in the column direction, and arranged in the staggered manner respectively in the row direction and the column direction. Pairs of word lines separated from each other intersect (orthogonally, in this example) with the plural active regions AR spaced at one column intervals. The relationships are similar in the memory cell array areas (not shown) of other rows within the area A and outside the area A.

The common bit line contact BLC23_1 and a common bit line contact BLC23_2 are respectively provided in center parts of the active regions AR located at one column intervals between two word lines (WL<2> and WL<3>) forming the pair of word lines. Similarly, the common bit line contact BLC45_1 and a common bit line contact BLC45_2 are respectively provided in center parts of the active regions AR located at one column intervals between two word lines (WL<4> and WL<5>) forming the other pair of word lines.

The source line contacts SLC are provided near the ends of the respective active regions AR. The SCL in the number twice the number of the BLC (per area) are provided in the parts of the active regions AR extending between two word lines adjacent to each other (for example, between WL<3> and WL<4> or WL<5> and WL<6>) and contained in the different pairs of word lines.

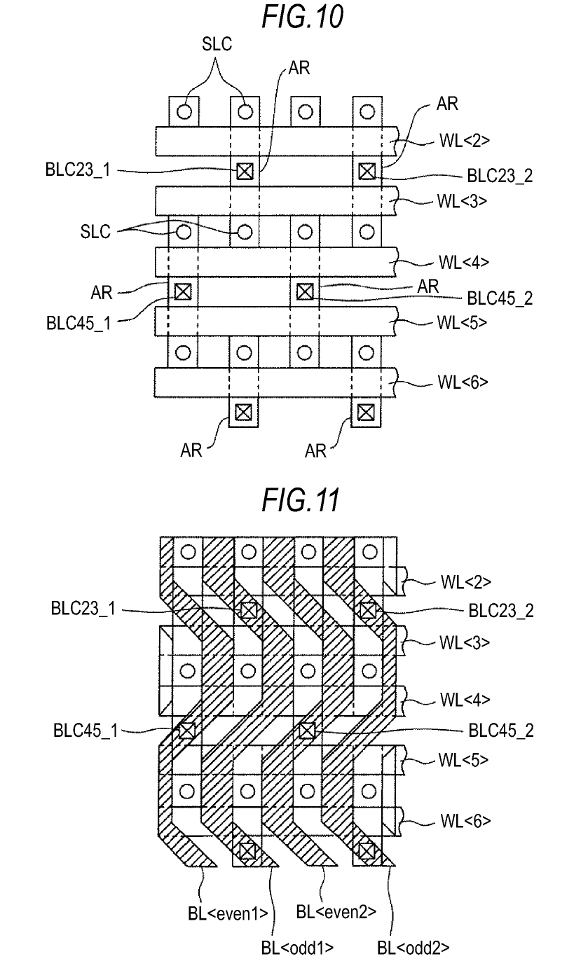

FIG. 11 is a plan view after bit lines BL are formed from the state in FIG. 10 and source line contacts SLC are further formed.

The four bit lines, i.e., BL<even1>, BL<odd1>, BL<even2>, BL<odd2> meander around the source line contacts SLC. Further, the respective bit lines commonly connect the common bit line contacts BLC within the same memory cell columns through between the active region parts with the source line contacts SLC provided thereon.

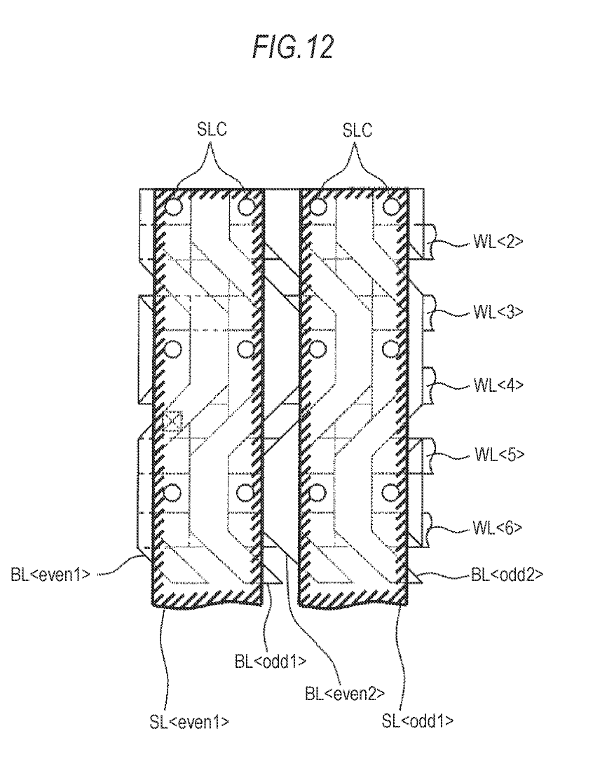

FIG. 12 is a plan view after variable resistive elements Rcell (not shown, see FIG. 13) are formed in the upper parts of the source line contacts SLC from the state in FIG. 11, and source lines SL are further formed on the interlayer insulating film in which the source line contacts SLC have been embedded.

The source lines SL in the embodiment have a width corresponding to two memory cells and are wired to extend in the column direction to cover the upper surfaces of all source line contacts SLC within the two memory cell columns.

Note that, in the case where the word lines WL and bit lines BL are formed in the minimum working dimension F, the width (i.e., line) of the source lines SL is 2 F and the separated distances (i.e., spaces) between the source lines SL are F. In this case, given that the minimum working dimension is F, the unit area per memory cell is 8 F².

### Modified Example 1

FIG. 14 shows a modified example of a worked shape of the source lines SL.

As shown in FIG. 14, the worked shape of the source lines SL may be formed to be wider in the parts of the source line contacts SLC and narrower in the other parts. In the worked shape, there is an advantage that the average width of the space is wider and extraction of the wiring materials (removability of the etched parts) is improved, and the yield is better by that.

Thereby, regarding the source lines, the line width in the row direction may be made smaller than twice the distance between lines in the row direction.

### Modified Example 2

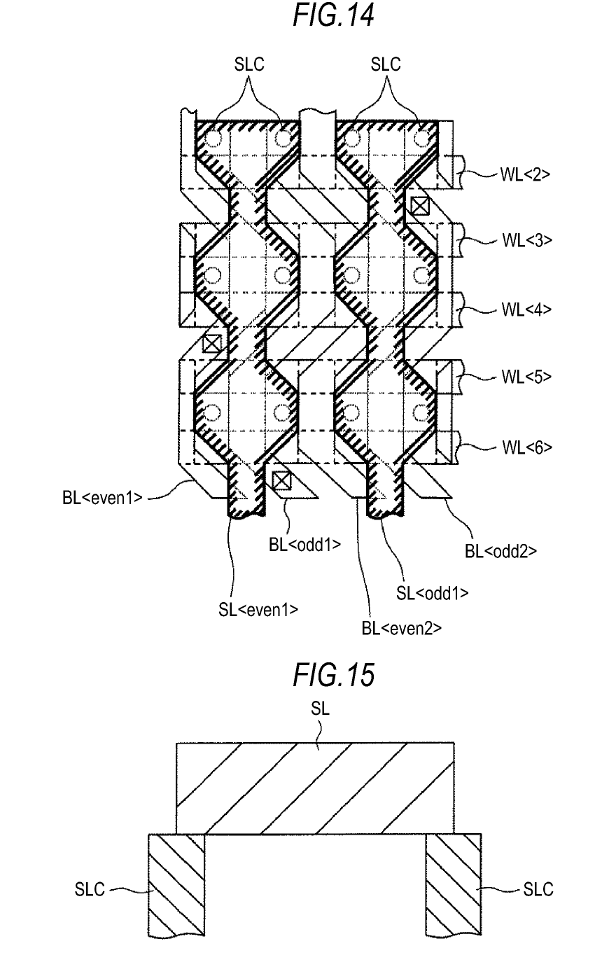

FIG. 15 shows a modified example of an overlapping width of the source line contacts SLC and the source line SL.

As shown in FIG. 15, there may be no harm in memory characteristics unless the upper surfaces of the source line contacts SLC are completely covered by the source lines SL. The diameter of the variable resistive element Rcell may be made smaller than the diameter of the source line contact SLC depending on the structure of the variable resistive element Rcell (not shown in FIG. 15).

Thereby, regarding the source lines, the line width in the row direction may be made smaller than twice the distance between lines in the row direction.

### Drive Circuit and Operation Example

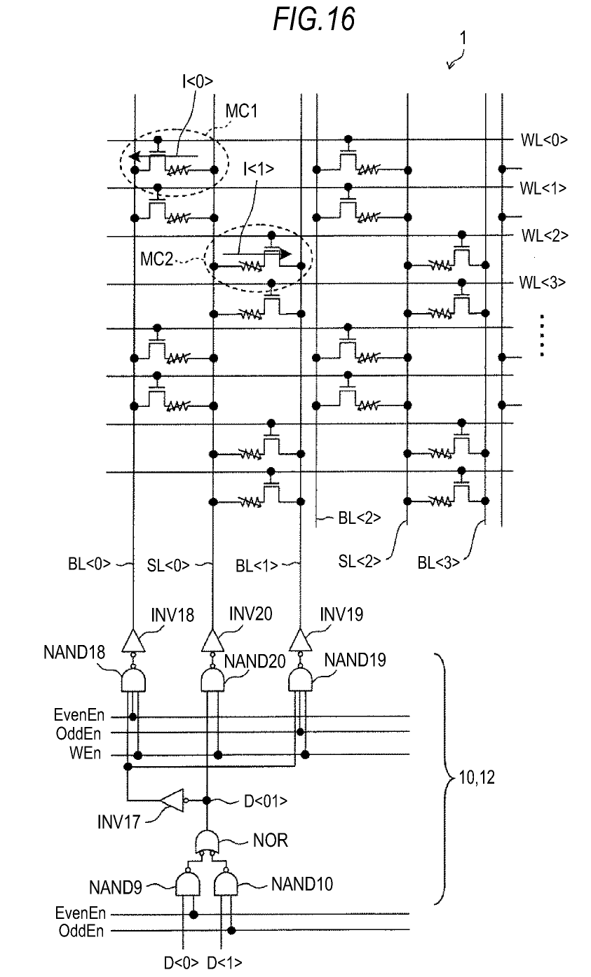

FIG. 16 shows a circuit of a main part of the BL driver 10 and the SL driver 12 connected to the memory cell array 1.

The drive circuit (10, 12) illustrated in FIG. 16 includes five NAND circuits NAND9, NAND10, NAND18 to NAND20, one NOR circuit, and four inverters INV17 to INV20.

Data D<0> and D<1> sent from the I/O buffer 9 in FIG. 4 are respectively provided to one inputs of the NAND circuits NAND9 and NAND10. An even column enable signal (EvenEn) is provided to the other input of the NAND circuit NAND9 and an odd column enable signal (OddEn) is provided to the other input of the NAND circuit NAND10.

From the respective outputs of the NAND circuits NAND9 and NAND10, the NOR circuit NOR generates intermediate data D<01>. The output of the NOR circuit NOR is connected to one input of the NAND circuit NAND20. Further, the output of the NOR circuit NOR is connected to the first inputs of the NAND circuits NAND18 and NAND19 through the inverter INV17. An even column enable signal (EvenEn) is provided to the second input of the NAND circuit NAND18 and an odd column enable signal (OddEn) is provided to the second input of the NAND circuit NAND19. Write enable signals (WEn) are provided to the third inputs of the NAND circuits NAND18 and NAND19 and the other input of the NAND circuit NAND20.

The bit line BL<0> is driven by the inversion output of the NAND circuit NAND18, the source line SL<0> is driven by the inversion output of the NAND circuit NAND20, and the bit line BL<1> is driven by the inversion output of the NAND circuit NAND19.

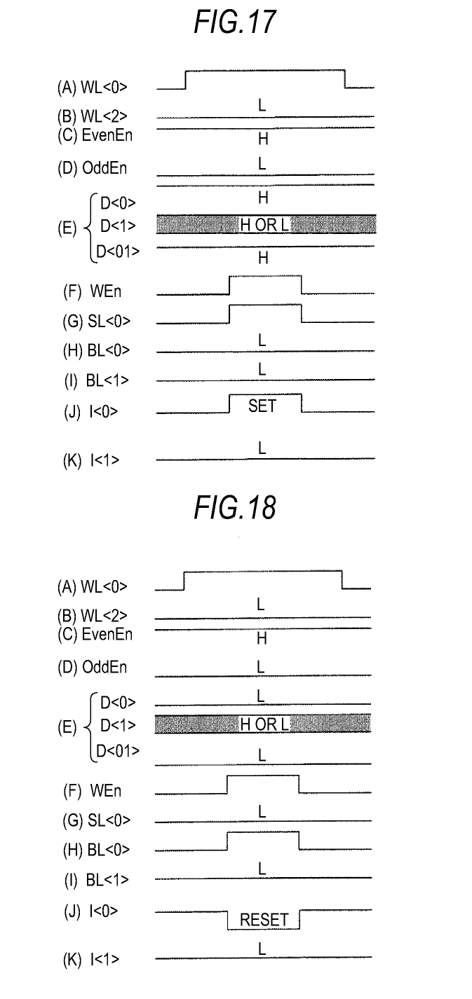

FIGS. 17 to 20 show waveform charts of set operation and reset operation for memory cells MC1 and MC2 in FIG. 16 by driving of the word line WL<0> and the word line WL<2>, respectively.

In the drive circuit in FIG. 16, if D<0>=H ((E) in FIG. 17), the set operation becomes enable and, if D<0>=L ((E) in FIG. 18), the reset operation becomes enable. Further, when the odd bit line is selected, even column enable signal (EvenEn)=H, and, when the odd bit line is selected, odd column enable signal (OddEn)=H.

When the memory cell MC1 is set ((A) to (K) in FIG. 17), first, the word line WL<0> is selected. When the word line WL<0> is selected, the memory cell at the bit line <0> side is selected and the memory cell at the bit line <1> side is non-selected. Ina state in which the word line WL<0> is raised to H ((A) in FIG. 17), pulses of the write enable signals (WEn) are generated. In this regard, the source line <0> and the bit line <0> are inverted in response to D<0>. The bit line <1> is in the non-operating state. In the state in which word line WL<0>=H, source line <0>=H and bit line <0>=L, and thus, a current I<0> flows in the set direction in the memory cell R<0> and the set operation is executed. Under the condition, the word line WL for selecting the bit line <1> is off, and no disturbance occurs in the memory cell connected to the bit line <1>.

When the memory cell MC1 is reset ((A) to (K) in FIG. 18), the above described operation is executed with the D<0> set to L. Thereby, the current I<0> flows in the opposite direction to the direction shown in FIG. 16 in the memory cell MC1, and the reset operation is executed.

On the other hand, when the memory cell MC2 is set ((A) to (K) in FIG. 19), an operation similar to the above described operation is executed with even column enable signal (EvenEn)=L and odd column enable signal (OddEn)=H.

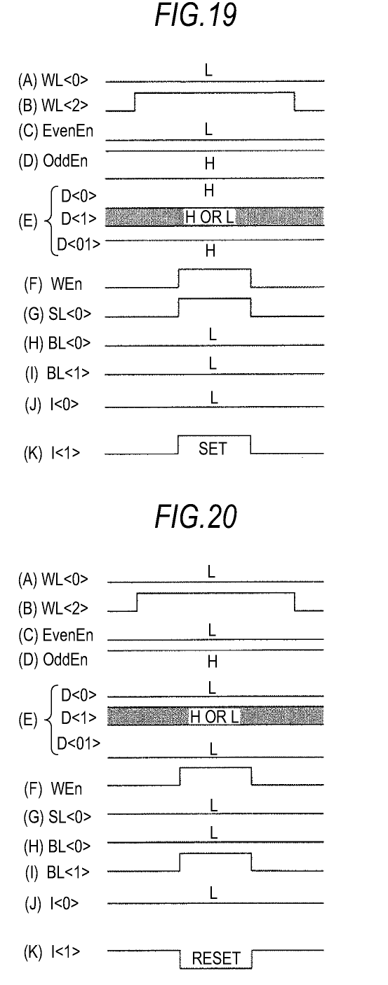

Further, when the memory cell MC2 is reset ((A) to (K) in FIG. 20), D<0>=L is input with (EvenEn)=L and (OddEn)=H.

In the embodiment, the memory cell array in which the bit line contacts BLC are shared and odd selection and even selection may be executed using arbitrary word lines may be realized. Further, in the case where the bit lines BL are worked in the minimum working dimension F for reduction of the cell size, the integration difficulty may be relaxed by making the wiring pitch of the source lines SL in the upper layer larger than the minimum working dimension F, and the reduction of yield in wiring formation may be prevented.

Furthermore, both the source lines and bit lines are worked in lines, and thus, the load is lighter and the configuration is suitable for high-speed operation.

As described above, the resistance random access change memory device having the higher speed and the high yield and the minute memory cells with the unit area per memory cell reduced to about 8F² may be realized.

Note that, using the modified examples 1, 2 or the like, the width of the source lines SL may be made smaller so that a ratio between line and space may be closer to 1:1, and thereby, the further improvement of the yield may be achieved.

### 2. Second Embodiment

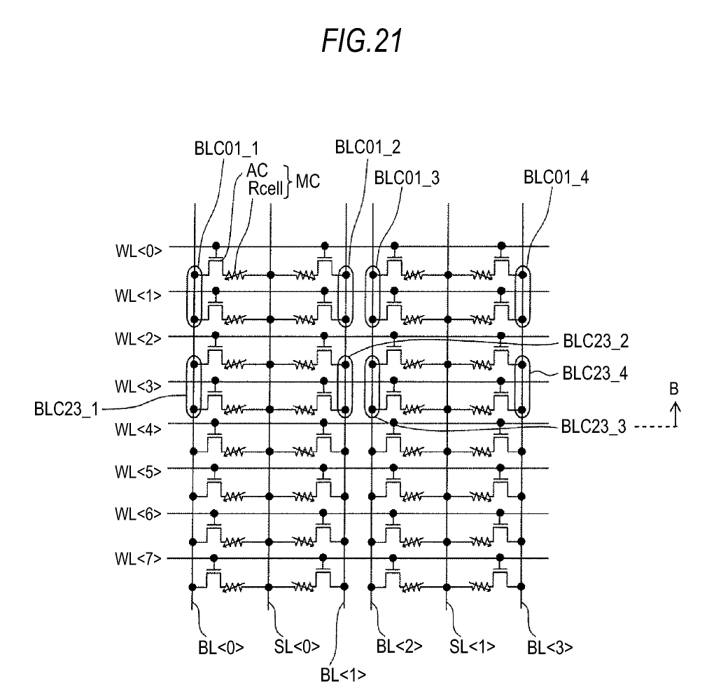

FIG. 21 shows an equivalent circuit diagram of a memory cell array 1 related to the second embodiment.

In the memory cell array 1 illustrated in FIG. 21, compared to FIG. 9, pairs of memory cells having common bit line contacts are arranged in a matrix with doubled density.

Further, the pairs of memory cells are connected to the adjacent respective bit lines to be selectable by all word lines. Furthermore, the memory cell array 1 has an arrangement of pairs of memory cells selected by the same word lines between the pairs of memory cells connected to the odd-numbered bit lines BL<1>, BL<3>, . . . and the pairs of memory cells connected to the even-numbered bit lines BL<0>, BL<2>, . . . .

In the arrangement of memory cells, given that the minimum working dimension is F, the unit area per memory cell is 6 F².

FIGS. 22 to 24 show plan views halfway through formation. These plan views correspond to area B in FIG. 21.

FIG. 22 is a plan view showing formation of diffusion layers (sources (regions) S and drains (regions) D) to common bit line contacts BLC.

As shown in FIG. 22, active regions AR with respect to each pair of transistors are formed in a rectangular shape longitudinal in the column direction. Pairs of word lines separated from each other intersect (orthogonally, in this example) with the plural active regions AR in the row direction. The relationships are similar in the memory cell array areas (not shown) of other rows in the area B and outside the area B.

The common bit line contacts BLC01_1, BLC01_2, BLC01_3, BLC01_4 are respectively provided in center parts of the active regions AR located between two word lines (WL<1> and WL<2>) forming the pair of word lines. Similarly, the common bit line contacts BLC23_1, BLC23_2, BLC23_3, BLC23_4 are respectively provided in center parts of the active regions AR located between two word lines (WL<3> and WL<4>) forming the other pair of word lines.

The source line contacts SLC are provided near the ends of the respective active regions AR. Accordingly, the source line contacts SCL in the number twice the number of the bit line contacts BLC (per area) are provided in the parts of the active regions AR extending between two word lines (for example, between WL<1> and WL<2>) adjacent to each other and contained in the different pairs of word lines.

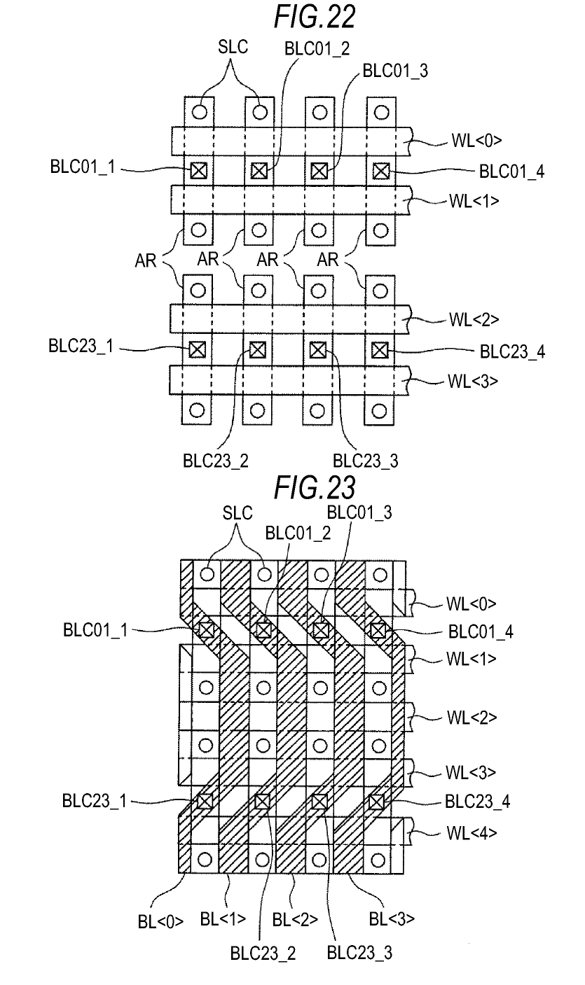

FIG. 23 is a plan view after bit lines BL are formed from the state in FIG. 22 and source line contacts SLC are further formed.

The four bit lines, i.e. , BL<0> to BL<3> meander around the source line contacts SLC. Further, the bit lines commonly connect the common bit line contacts BLC within the same memory cell columns through between the active region parts with the source line contacts SLC provided thereon.

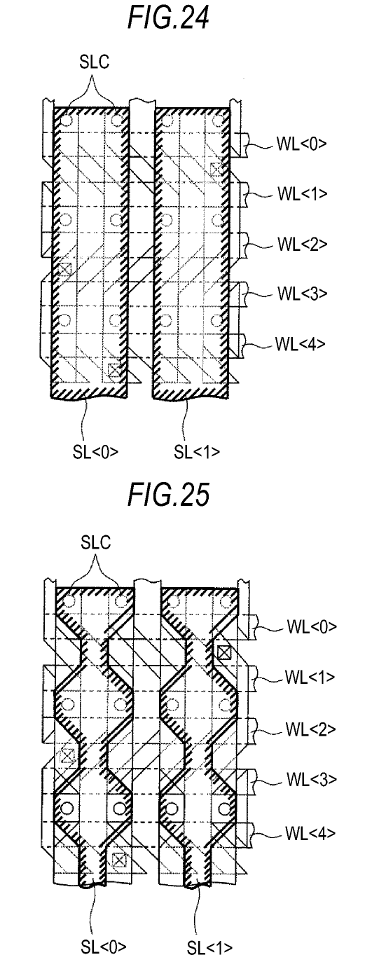

FIG. 24 is a plan view after variable resistive elements Rcell (not shown, see FIG. 13) are formed in the upper parts of the source line contacts SLC from the state in FIG. 23, and source lines SL are further formed on the interlayer insulating film in which the source line contacts SLC have been embedded.

The source lines SL in the embodiment have a width corresponding to two memory cells and are wired to extend in the column direction to cover the upper surfaces of all source line contacts SLC within the two memory cell columns.

Note that, in the case where the word lines WL and bit lines BL are formed in the minimum working dimension F, the width (i.e. , line) of the source lines SL is 2 F and the separated distances (i.e., spaces) between the source lines SL are F. In this case, given that the minimum working dimension is F, the unit area per memory cell is 4 F².

### Modified Example 3

FIG. 25 shows a modified example of a worked shape of the source lines SL.

As shown in FIG. 25, the worked shape of the source lines SL may be formed to be wider in the parts of the source line contacts SLC and narrower in the other parts. In the worked shape, there is an advantage that the average width of the space is wider and extraction of the wiring materials (removability of the etched parts) is improved, and the yield is better by that.

Thereby, regarding the source lines, the line width in the row direction may be made smaller than twice the distance between lines in the row direction.

### Drive Circuit and Operation Example

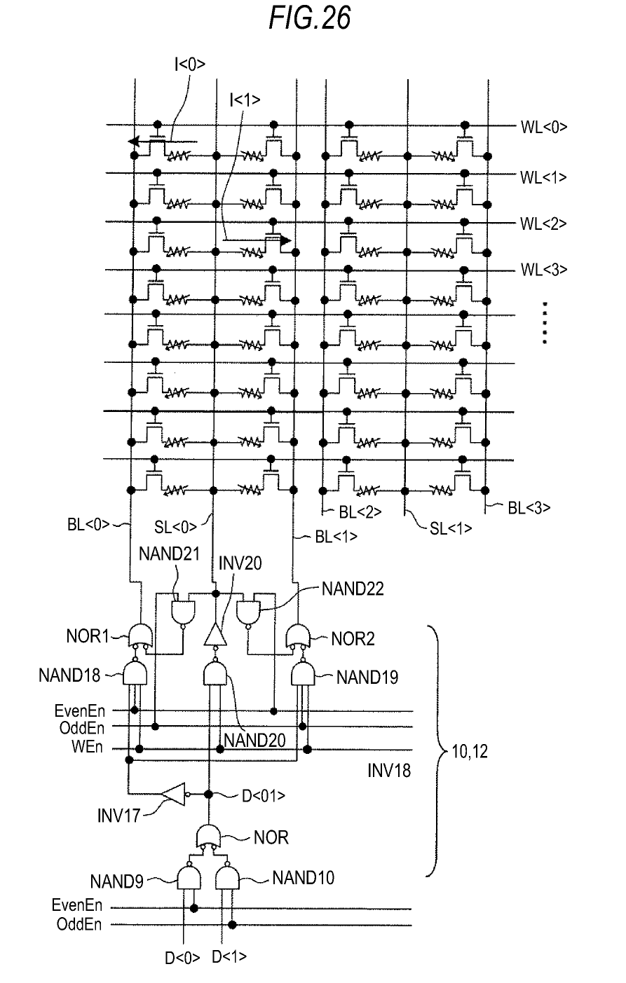

FIG. 26 shows a circuit of a main part of the BL driver 10 and the SL driver 12 connected to the memory cell array 1.

The drive circuit (10, 12) illustrated in FIG. 26 includes NAND circuits NAND21, NAND22 in addition to the configuration in FIG. 16. Further, an NOR circuit NOR1 is provided in place of the inverter INV18 and an NOR circuit NOR2 is provided in place of the inverter INV19.

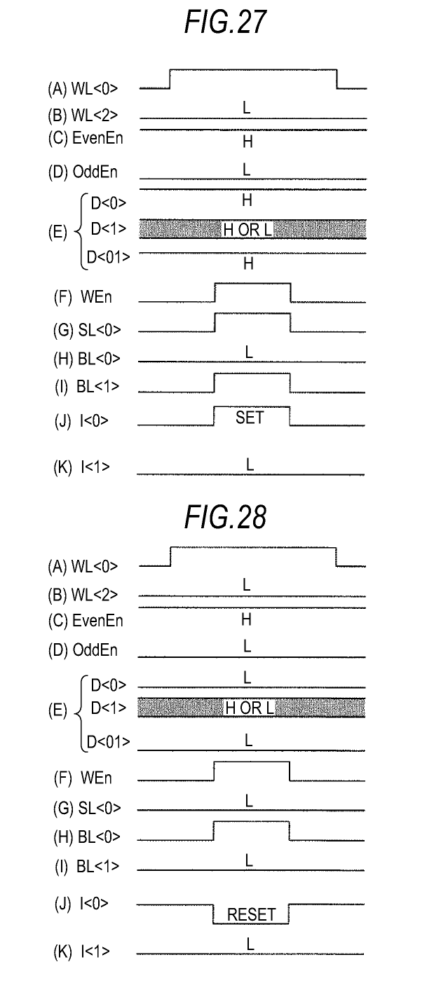

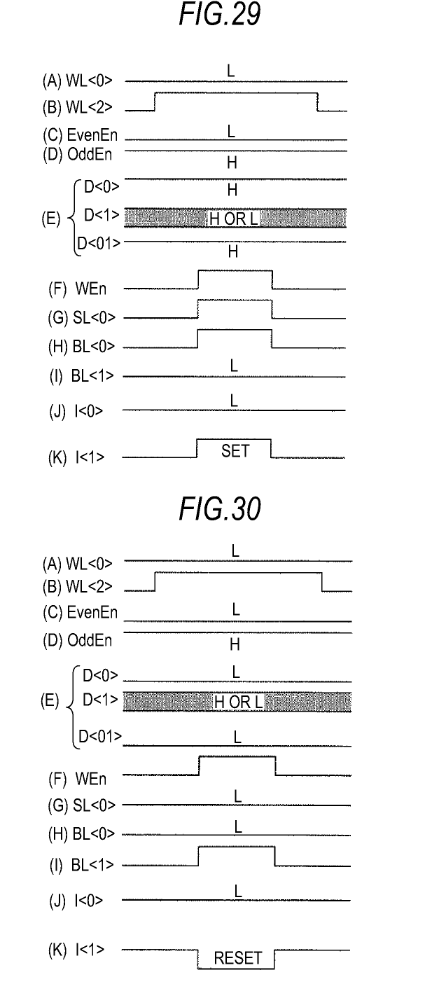

FIGS. 27 to 30 show waveform charts of set operation and reset operation for memory cells MC1 and MC2 in FIG. 16 by driving of the word line WL<0> and the word line WL<2>, respectively.

The operation is the same as that of the first embodiment, and the explanation will be omitted.

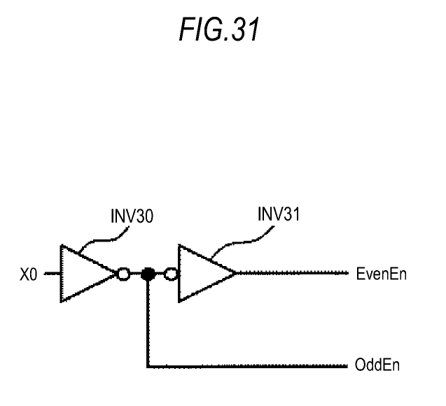

FIG. 31 shows a generation circuit part of enable signals usable in the first and second embodiments.

The circuit part allows input XO pass through two inverters INV30 and INV31 to obtain an odd column enable signal (OddEn) from the output of the inverter INV30 and an even column enable signal (EvenEn) from the output of the inverter INV31.

The present disclosure contains subject matter related to that disclosed in Japanese Priority Patent Application JP 2010-133295 filed in the Japan Patent Office on Jun. 10, 2010, the entire contents of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A resistance random access change memory device comprising:
a memory cell array in which plural memory cells having current paths with series-connected access transistors and variable resistive elements are two-dimensionally arranged;
plural bit lines that connect one ends of the current paths;
plural source lines that connect the other ends of the current paths; and
plural word lines that control conduction and non-conduction of the access transistors,
wherein bit line contacts are shared between two memory cells to which the word lines are adjacently provided, and pairs of memory cells are formed,
all of the pairs of memory cells connected to the adjacent two bit lines are connected to the corresponding source lines via individual source line contacts, and
the source lines are formed by a wiring layer upper than that of the bit lines with a larger pitch than that of the bit lines.

2. The resistance random access change memory device according to claim 1, wherein the pairs of memory cells are alternately connected to the adjacent two bit lines in a column direction.

3. The resistance random access change memory device according to claim 1, wherein the memory cell array has an arrangement of pairs of memory cells selected by different word lines between the pairs of memory cells connected to odd-numbered bit lines and the pairs of memory cells connected to even-numbered bit lines.

4. The resistance random access change memory device according to claim 1, wherein active regions with respect to each pair of memory cells are formed in a rectangular shape longitudinal in a column direction, and arranged in a staggered manner respectively in a row direction and the column direction,
pairs of word lines separated from each other intersect with the plural active regions spaced at one column intervals in the row direction, and the intersection of the pairs of word lines with the active regions is repeated in the column direction,
the shared bit line contacts are provided in center parts of the active regions located at one column intervals between two word lines forming the pairs of word lines,
the source line contacts in a number twice the number of the bit line contacts are provided in the parts of the active regions extending between two word lines adjacent to each other and contained in the different pairs of word lines,
the bit lines commonly connecting the bit line contacts with respect to each column are wired to meander through between the parts of the active regions with the source line contacts provided thereon, and
the source lines wider than the bit lines and including the upper wiring layer commonly connect all of the source line contacts in the memory cell arrangement of two columns and are wired in the column direction.

5. The resistance random access change memory device according to claim 1, wherein the pairs of memory cells in a number selectable by all word lines are connected to the respective adjacent two bit lines.

6. The resistance random access change memory device according to claim 5, wherein the memory cell array has an arrangement of pairs of memory cells selected by the same word lines between the pairs of memory cells connected to odd-numbered bit lines and the pairs of memory cells connected to even-numbered bit lines.

7. The resistance random access change memory device according to claim 5, wherein active regions with respect to each pair of memory cells are formed in a rectangular shape longitudinal in the column direction, and arranged in a matrix,
pairs of word lines separated from each other intersect with the plural active regions spaced in the row direction, and the intersection of the pairs of word lines with the active regions is repeated in the column direction,
the shared bit line contacts are provided in center parts of the active regions located between two word lines forming the pairs of word lines,
the source line contacts in a number twice the number of the bit line contacts are provided in the parts of the active regions extending between two word lines adjacent to each other and contained in the different pairs of word lines,
the bit lines commonly connecting the bit line contacts with respect to each column are wired to meander through between the parts of the active regions with the source line contacts provided thereon, and
the source lines wider than the bit lines and including the upper wiring layer commonly connect all of the source line contacts in the memory cell arrangement of two columns and are wired in the column direction.

8. The resistance random access change memory device according to claim 1, wherein the source lines have a line width in the row direction smaller than a distance between lines in the row direction.

9. The resistance random access change memory device according to claim 1, wherein the variable resistive elements are provided between contact plugs of the source line contacts and the source lines.

10. The resistance random access change memory device according to claim 9, wherein the source lines have a line width with edges overlapping with parts of resistance change layers of the variable resistive elements.

11. The resistance random access change memory device according to claim 4, wherein the source lines have a width narrower in parts other than in parts connecting to the source line contacts in the memory cell arrangement of two columns.

12. The resistance random access change memory device according to claim 1, further comprising drive circuits that can independently control the memory cells in odd rows and the memory cells in even rows.

13. The resistance random access change memory device according to claim 1, wherein the variable resistive elements are resistance random access change memory elements having different logic of write information depending on a direction of an applied voltage.
